(19) United States
(12) Patent Application Publication
(10) Pub. No.: US 2015/0024201 A1
(43) Pub. Date: Jan. 22, 2015

(54) CYLINDRICAL GRAPHENE NANORIBBON ON METAL

(71) Applicant: Lockheed Martin Corporation, Bethesda, MD (US)

(72) Inventors: Danielle Williams, Santa Barbara, CA (US); Rebecca Schwartz, Chester Springs, PA (US)

(21) Appl. No.: 13/944,695

(22) Filed: Jul. 17, 2013

(51) Int. Cl. C01B 31/04; C23C 14/18; B23K 26/36

(52) U.S. Cl. CPC C01B 31/0446; B23K 26/365; C23C 14/18
USPC 428/368; 427/555

(57) ABSTRACT

Three-dimensional (3D) graphene nanoribbons and methods for fabricating 3D graphene nanoribbons that may readily function as solenoid windings and the like. In one embodiment, a method of fabricating a 3D graphene nanoribbon (100) may include coating a side surface (102A) of a 3D insert (102) with a metal (104) appropriate for graphene growth thereon. The method may also include growing a layer (106) of graphene directly on the metal coating. The method may also include removing a strip of the graphene layer and metal coating (106/104) to expose the side surface (102A) of the insert (102) while leaving a line (108) of graphene on metal winding around the insert (102) and extending continuously from a first end (108A) of the line (108) to a second end (108B) of the line (108).

### FIELD OF THE INVENTION

The present invention relates generally to the fabrication of graphene nanoribbons (GNRs), and more particularly to three-dimensional (3D) GNRs and their fabrication.

### BACKGROUND OF THE INVENTION

Graphene is generally understood to be a pure carbon substance that is an allotrope of carbon whose structure is a single planar sheet of sp²-bonded carbon atoms densely packed in a honeycomb crystal lattice structure. GNRs are ultra-thin lines of graphene. Since graphene exhibits properties such as high carrier mobility, GNRs have been considered for use in high-performance electronic devices such as, for example, as conductors for solenoid windings. Two-dimensional (2D) fabrication techniques where long GNRs are fabricated on flat surfaces are possible. However, in order to use long GNRs as solenoid windings or in other generally 3D applications, challenging lift-off techniques must be undertaken in order to remove 2D fabricated GNRs from the surfaces on which they are formed. Given their ultra-thin nature, breaks, cracks, or other discontinuities may readily occur during such lift-off processes.

### SUMMARY OF THE INVENTION

Accordingly, 3D graphene nanoribbons and methods for fabricating 3D graphene nanoribbons that may readily be utilized in a variety of devices including, for example as solenoid windings and the like, are provided.

In one aspect, a method of fabricating a 3D graphene nanoribbon may include coating a side surface of a 3D insert with a metal appropriate for graphene growth thereon. The method may also include growing a layer of graphene directly on the metal coating. The method may also include removing a strip of the graphene layer and metal coating to expose the side surface of the insert while leaving a line of graphene on metal winding around the insert and extending continuously from a first end of the line to a second end of the line.

In another aspect, a 3D graphene nanoribbon may include a 3D insert having a side surface thereof coated with a metal appropriate for graphene growth thereon. The 3D graphene nanoribbon may also include a layer of graphene grown directly on the metal coating. The 3D graphene nanoribbon may also include a line of graphene on metal winding around the insert and extending continuously from a first end of the line to a second end of the line. The line may be formed by removing a strip of the graphene layer and metal coating to expose the side surface of the insert and leaving the graphene on metal line remaining on the side surface of the insert.

Various refinements exist of the features noted in relation to the various aspects of the present invention. Further features may also be incorporated in the various aspects of the present invention. These refinements and additional features may exist individually or in any combination, and various features of the various aspects may be combined. These and other aspects and advantages of the present invention will be apparent upon review of the following Detailed Description when taken in conjunction with the accompanying figures.

### DESCRIPTION OF THE DRAWINGS

For a more complete understanding of the present invention and further advantages thereof, reference is now made to the following Detailed Description, taken in conjunction with the drawings, in which:

FIGS. 1A-1B are side perspective and end views, respectively, of one embodiment of a 3D graphene nanoribbon;

FIG. 2 shows the steps of one embodiment of a method of fabricating a 3D graphene nanoribbon; and

FIGS. 3A-3D illustrate possible manners of accomplishing a removal step included in the method of FIG. 2.

### DETAILED DESCRIPTION

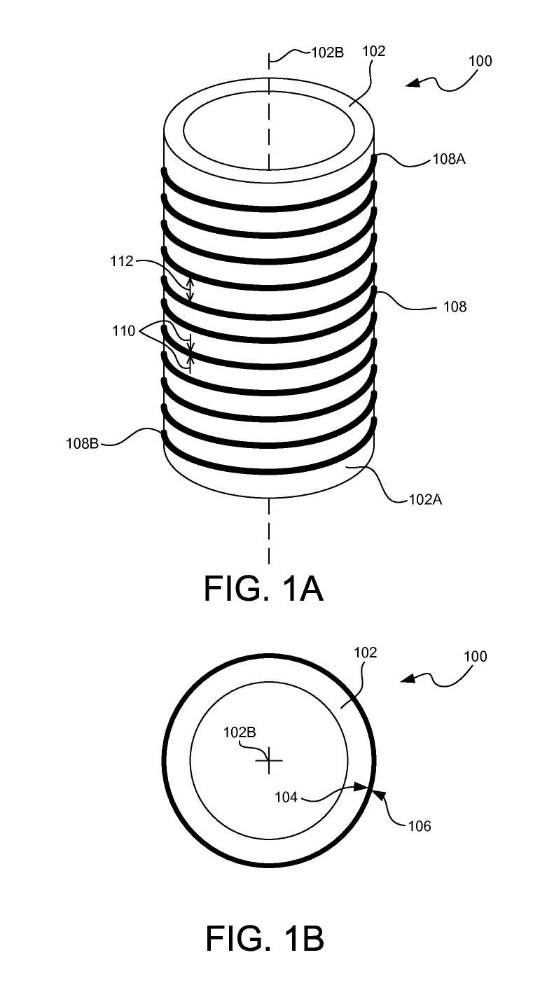

FIGS. 1A-1B show side perspective and end views of one embodiment of a three-dimensional (3D) graphene nanoribbon 100. The 3D graphene nanoribbon 100 is formed on the side surface 102A of an insert 102 having a circular or elliptical cross-section and a longitudinal axis 102B. In this regard, the insert 102 may, for example, be a cylinder, a cone or the like. In other embodiments, it may be possible for the insert 102 to have differently a shaped cross-section such as, for example, triangular, rectangular, pentagonal, hexagonal, etc. The insert 102 may be comprised of a ceramic material (e.g., silicon). The insert 102 may be appropriately sized (e.g., in height and diameter), in order to accommodate formation of a sufficient number of windings thereon for the intended application of the 3D graphene nanoribbon 100. As depicted in FIGS. 1A-1B, the insert 102 may be hollow. In other embodiments, the insert 102 may be solid.

The side surface 102A of the insert 102 has a metallic coating 104. A sputter coating process may be used to provide the metallic coating 104 on the side surface 102A of the insert 102. The metallic coating 104 comprises a metal appropriate for graphene growth thereon. In this regard, the metallic coating 104 may, for example, include metals such as copper, nickel or any other metal alloys appropriate for the growth of graphene thereon. A layer of graphene 106 is grown directly on the metal coating 104.

A continuous strip of the metallic coating 104 and the graphene layer 106 grown thereon are removed from the insert 102 exposing a portion of the side surface 102A of the insert 100 and leaving a continuous graphene on metal line 108. The continuous graphene on metal line 108 may wind around the side surface 102A of the insert 102 in a helical fashion from a first end 108A of the graphene on metal line 108 proximal to one end of the insert 100 to a second end 108B of the graphene on metal line 108 proximal to the opposing end of the insert 102. The continuous graphene on metal line 108 may have a desired width 110. In this regard, the desired width 110 may, for example, be 1.10 microns or less. There may also be a desired spacing 112 between adjacent windings. In this regard, the desired spacing may, for example, be about 2.00 microns or less. In some embodiments such as shown, the width 110 and/or spacing 112 may be consistent over the length of the graphene on metal line 108. In other embodiments, the width 110 and/or spacing 112 may vary over the length of the graphene on metal line 108.

A length of the insert 102 measured along its longitudinal axis 102B may be selected depending upon how many windings of the graphene on metal line 108 are desired as well as the width 110 of the graphene on metal line 108 and the spacing 112 between adjacent windings of the graphene on metal line 108. It should be noted that the figures are not drawn to scale, and, thus an actual 3D graphene nanoribbon 100 could have many more windings of the graphene on metal line 108 formed on the insert 100 than depicted.

Removal of the portion of the metallic coating 104 and the graphene layer 106 grown thereon may be accomplished in a variety of manners including, for example, by using an ablation tool. The ablation tool may be used to ablate the strip of the metallic coating 104/graphene layer 106 that is to be removed leaving the continuous graphene on metal line 108. In one embodiment, the ablation tool may comprise a laser.

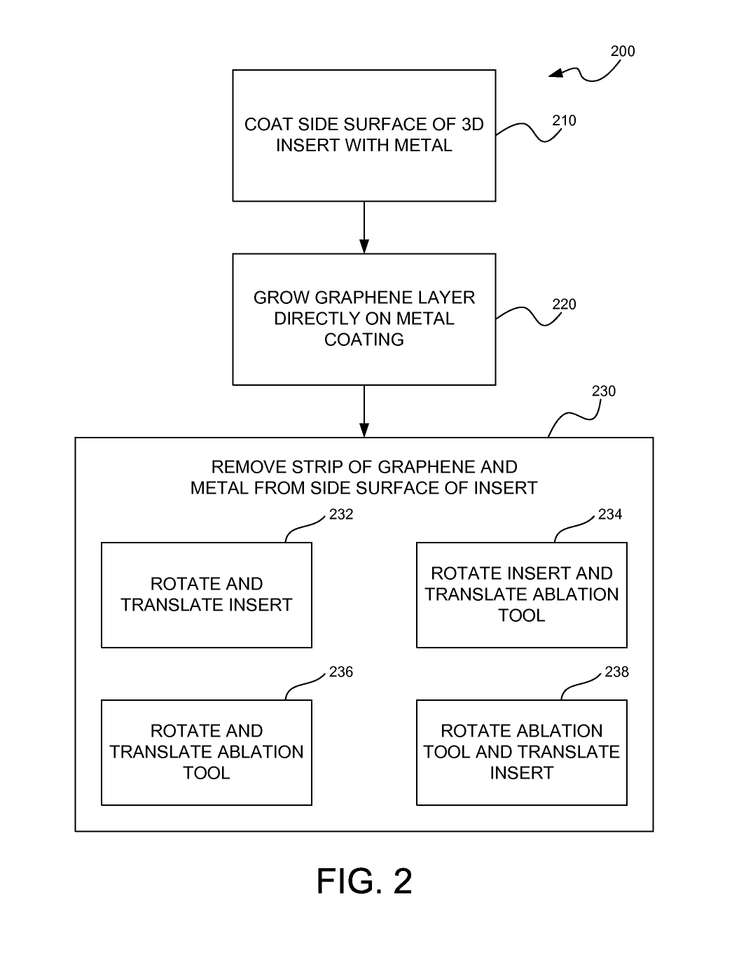

FIG. 2 shows the steps that may be included in one embodiment of a method 200 for fabricating a 3D graphene nanoribbon. In step 210 of the method 200, a side surface of a 3D insert is coated with a metal appropriate for graphene growth thereon. The 3D insert may be comprised of ceramic material (e.g., silicon) and may have a circular or elliptical cross-section. In this regard, the 3D insert may be a cylindrically shaped insert or a conical shaped insert. In other embodiments, the 3D insert may also have different cross sections (e.g. triangular, rectangular, pentagonal, hexagonal, etc.). Step 210 may be accomplished by sputter coating the side surface of the insert with the metal. Various metals may be used to coat the side surface of the 3D insert including, for example copper, nickel and any other metal alloys appropriate for graphene growth thereon.

In step 220, a layer of graphene is grown directly over the metal coating.

In step 230, a strip of the graphene layer and metal coating is removed to expose the side surface of the insert. Removal of the strip leaves a line of graphene on metal winding around the insert in a helical fashion that extends continuously from a first end of the line to a second end of the line.

Step 230 may be accomplished in a variety of manners. In one embodiment, an ablation tool such as a laser may be used to remove the strip of the graphene layer and metal coating by directing a laser beam onto each portion of the strip for a sufficient amount of time to ablate (e.g., heat until the graphene and metal vaporize) the material being removed. Step 230 may involve one or more sub-steps to achieve the continuous graphene on metal line winding in a helical fashion around the side surface of the insert.

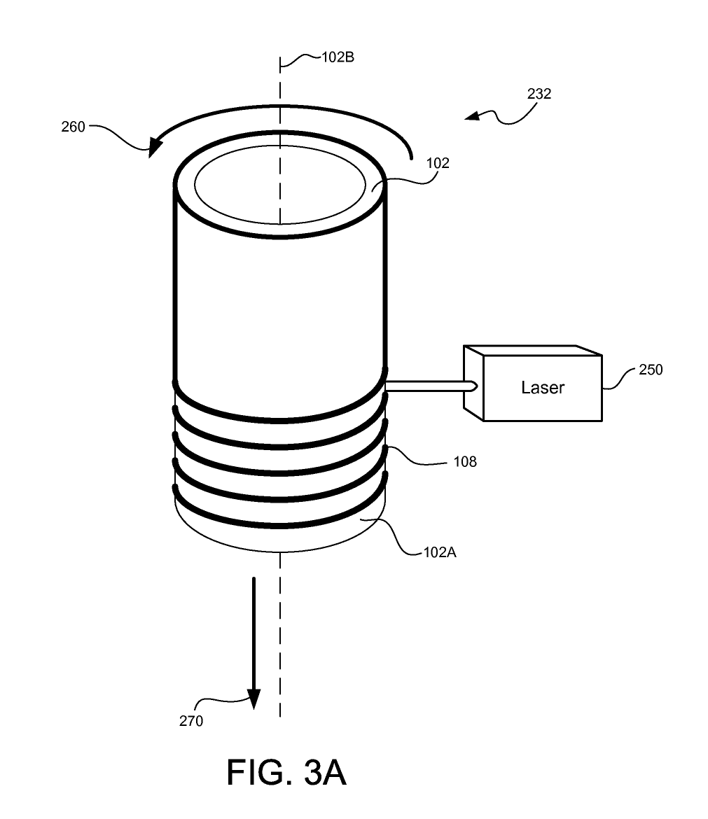

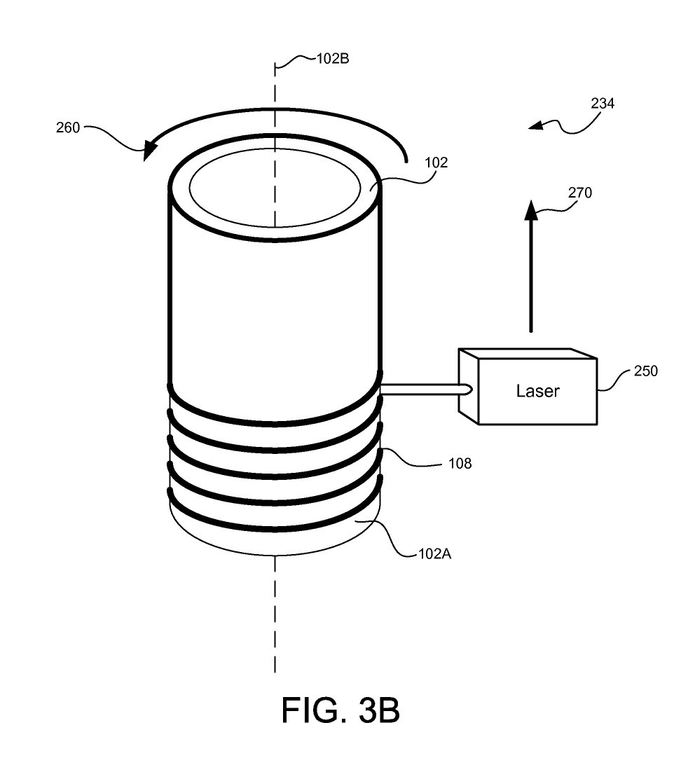

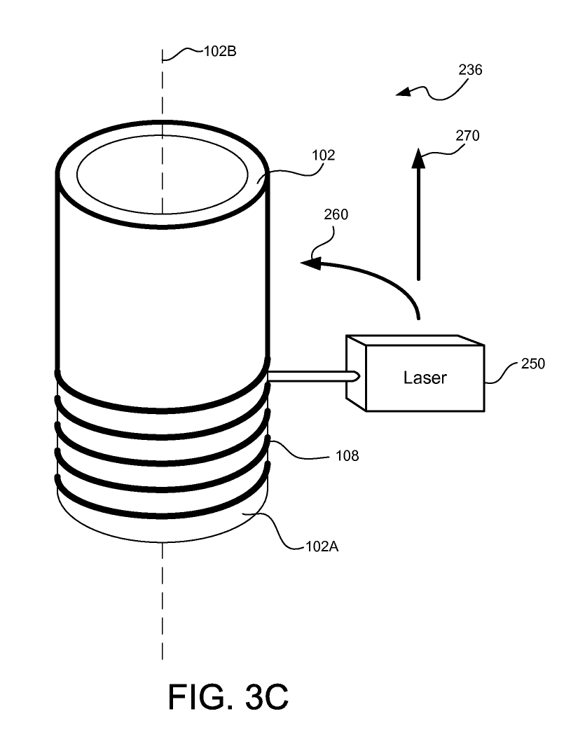

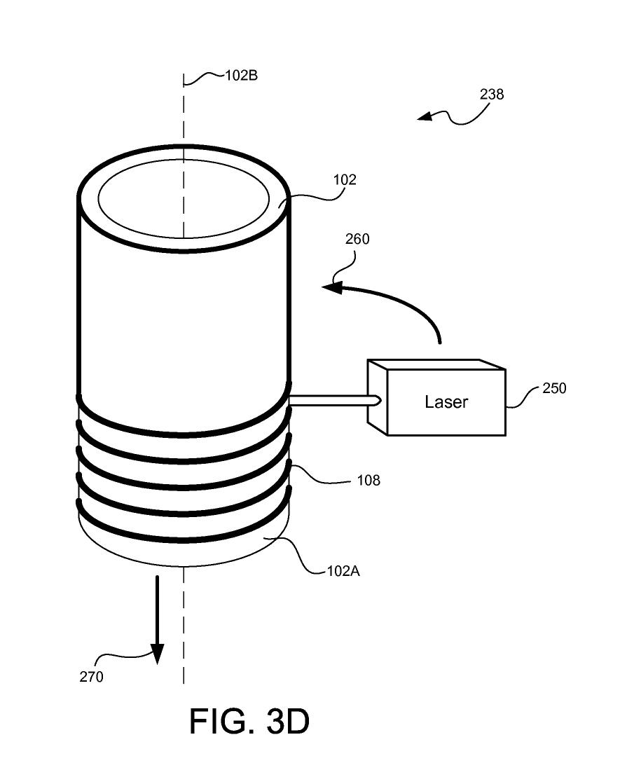

In sub-step 232, the insert is rotated around a longitudinal axis of the insert while translating the insert relative to the ablation tool in the direction of the longitudinal axis. FIG. 3A illustrates sub-step 232, in which a laser 250 is used as the ablation tool. As indicated by arrow 260, the insert 102 is rotated around the longitudinal axis 102B of the insert 102 while also translating the insert 102 relative to the laser 250 in the direction of the longitudinal axis 102B as indicated by arrow 270. As the insert 102 is rotated and translated, the laser 250 directs a laser beam 252 onto the metal coating/graphene layer 104/106 on the side surface 102A of the insert 102. The laser beam 252 is focused to ablate the metal coating/graphene layer 104/106 in a strip as the insert 102 is rotated and translated leaving a non-ablated continuous line 108 of graphene on metal winding in a helical fashion around the insert 102.

In sub-step 234, the insert is rotated around a longitudinal axis of the insert while translating the ablation tool in the direction of the longitudinal axis relative to the insert. FIG. 3B illustrates sub-step 234, in which a laser 250 is used as the ablation tool. As indicated by arrow 260, the insert 102 is rotated around the longitudinal axis 102B of the insert 102 while also translating the laser 250 relative to the insert 102 in the direction of the longitudinal axis 102B as indicated by arrow 270. As the insert 102 is rotated and laser 250 is translated, the laser 250 directs a laser beam 252 onto the metal coating/graphene layer 104/106 on the side surface 102A of the insert 102. The laser beam 252 is focused to ablate the metal coating/graphene layer 104/106 in a strip as the insert 102 is rotated and the laser 250 is translated leaving a non-ablated continuous line 108 of graphene on metal winding in a helical fashion around the insert 102.

In sub-step 236, the ablation tool is rotated around a longitudinal axis of the insert while translating the ablation tool in the direction of the longitudinal axis relative to the insert. FIG. 3C illustrates sub-step 236, in which a laser 250 is used as the ablation tool. As indicated by arrow 260, the laser 250 is rotated around the longitudinal axis 102B of the insert 102 while also translating the laser 250 relative to the insert 102 in the direction of the longitudinal axis 102B as indicated by arrow 270. As the laser 250 is rotated and translated, the laser 250 directs a laser beam 252 onto the metal coating/graphene layer 104/106 on the side surface 102A of the insert 102. The laser beam 252 is focused to ablate the metal coating/graphene layer 104/106 in a strip as the laser 250 is rotated and translated leaving a non-ablated continuous line 108 of graphene on metal winding in a helical fashion around the insert 102.

In sub-step 238, the laser is rotated around a longitudinal axis of the insert while translating the insert in the direction of the longitudinal axis relative to the laser. FIG. 3D illustrates sub-step 238, in which a laser 250 is used as the ablation tool. As indicated by arrow 260, the laser 250 is rotated around the longitudinal axis 102B of the insert 102 while also translating the insert 102 relative to the laser 250 in the direction of the longitudinal axis 102B as indicated by arrow 270. As the laser 250 is rotated and the insert 102 is translated, the laser 250 directs a laser beam 252 onto the metal coating/graphene layer 104/106 on the side surface 102A of the insert 102. The laser beam 252 is focused to ablate the metal coating/graphene layer 104/106 in a strip as the laser 102 is rotated and the insert 102 is translated leaving a non-ablated continuous line 108 of graphene on metal winding in a helical fashion around the insert 102.

While this disclosure contains many specifics, these should not be construed as limitations on the scope of the disclosure or of what may be claimed, but rather as descriptions of features specific to particular embodiments of the disclosure. Certain features that are described in this specification in the context of separate embodiments and/or arrangements can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Additionally, the foregoing description has been presented for purposes of illustration and description and is not intended to limit the invention to the form disclosed herein. Consequently, variations and modifications commensurate with the above teachings may be possible. It is intended that the appended claims be construed to include alternative embodiments to the extent permitted by the prior art.

What is claimed is:

1. A method of fabricating a three-dimensional graphene nanoribbon, said method comprising the steps of:
coating a side surface of a three-dimensional insert with a metal appropriate for graphene growth thereon;
growing a layer of graphene directly on the metal coating; and
removing a strip of the graphene layer and metal coating to expose the side surface of the insert while leaving a line of graphene on metal winding around the insert and extending continuously from a first end of the line to a second end of the line.

2. The method of claim 1 wherein said step of coating comprises sputter coating the insert with the metal.

3. The method of claim 1 wherein in said step of coating, the metal is selected from the group consisting of copper, nickel and alloys thereof

4. The method of claim 1 wherein in said step of coating, the insert comprises a ceramic material.

5. The method of claim 1 wherein in said step of coating, the insert comprises one of a cylindrically shaped insert and a conical shaped insert.

6. The method of claim 1 wherein said step of removing comprises using an ablation tool to ablate the strip of the graphene layer and metal coating that is removed.

7. The method of claim 6 wherein in said step of ablating, the insert is rotated around a longitudinal axis of the insert while translating the insert relative to the ablation tool in the direction of the longitudinal axis.

8. The method of claim 6 wherein in said step of ablating, the insert is rotated around a longitudinal axis of the insert while translating the ablation tool relative to the insert in the direction of the longitudinal axis.

9. The method of claim 6 wherein in said step of ablating, the insert is translated relative to the ablation tool in the direction of a longitudinal axis of the insert while rotating the ablation tool around the longitudinal axis.

10. The method of claim 6 wherein in said step of ablating, the ablation tool is rotated around a longitudinal axis of the insert while translating the ablation tool relative to the insert in the direction of the longitudinal axis.

11. The method of claim 6 wherein in said step of ablating, the ablation tool comprises a laser.

12. A three-dimensional graphene nanoribbon comprising:
a three-dimensional insert having a side surface thereof coated with a metal appropriate for graphene growth thereon;
a layer of graphene grown directly on the metal coating; and
a line of graphene on metal winding around said insert and extending continuously from a first end of the line to a second end of the line, said line being formed by removing a strip of said graphene layer and metal coating to expose said side surface of said insert.

13. The three-dimensional graphene nanoribbon of claim 12 wherein said strip is removed using an ablation tool while rotating one of the insert and the tool around a longitudinal axis of the insert and translating one of the insert and the tool relative to one another in the direction of the longitudinal axis.

14. The three-dimensional graphene nanoribbon of claim 13 wherein the ablation tool comprises a laser.

15. The three-dimensional graphene nanoribbon of claim 12 wherein the metal coating is formed by sputter coating said side surface of said insert with the metal.

16. The three-dimensional graphene nanoribbon of claim 12 wherein the metal is selected from the group consisting of copper, nickel and alloys thereof.

17. The three-dimensional graphene nanoribbon of claim 12 wherein said insert comprises a ceramic material.

18. The three-dimensional graphene nanoribbon of claim 12 wherein said insert comprises one of a cylindrically shaped insert and a conical shaped insert.

19. The three-dimensional graphene nanoribbon of claim 12 wherein said line of graphene on metal winding around the insert is about 1.1 microns or less in width.

20. The three-dimensional graphene nanoribbon of claim 12 wherein a spacing between adjacent windings of the line of graphene on metal is about 2.0 microns or less.
